(19) United States
(12) Patent Application Publication
(10) Pub. No.: US 2015/0035165 A1
(43) Pub. Date: Feb. 5, 2015

(54) INTERCONNECTION STRUCTURE OF SEMICONDUCTOR DEVICE

(71) Applicant: National Chiao Tung University, Hsinchu City (TW)

(72) Inventors: Kuan-Neng Chen, Hsinchu City (TW); Yao-Jen Chang, Hsinchu City (TW)

(73) Assignee: National Chiao Tung University, Hsinchu City (TW)

(21) Appl. No.: 14/086,995

(22) Filed: Nov. 22, 2013

(30) Foreign Application Priority Data
Jul. 30, 2013 (TW) 102127315

(51) Int. Cl. H01L 23/538

(52) U.S. Cl. CPC H01L 23/5384
USPC 257/774

(57) ABSTRACT

An interconnection structure of a semiconductor device is provided, where the interconnection structure is constructed in a semiconductor substrate. The interconnection structure includes a first through silicon via and a second through silicon via both penetrating the semiconductor substrate, and the first through silicon via is spaced from the second through silicon via by a distance ranged from 2 μm to 40 μm.

### CROSS-REFERENCE TO RELATED APPLICATION

This application claims the priority benefit of Taiwan application serial no. 102127315, filed on Jul. 30, 2013. The entirety of the above-mentioned patent application is hereby incorporated by reference herein and made a part of this specification.

### FIELD OF THE INVENTION

The disclosure relates to an interconnection structure. More particularly, the disclosure relates to an interconnection structure of a semiconductor device.

### DESCRIPTION OF RELATED ART

Generally speaking, three dimensional integrated circuits (3D ICs) have a plenty of advantages such as small form factor, high efficiency, low power consumption, heterogeneous integration, and the like. In the application of 3D ICs, in order to obtain communication function between different chips stacked together, vertical through silicon via (TSV) is necessary to electrically connect the chips disposed on the upper and lower layers. At present, the high latency caused during the signal transmission through TSV is above 50% of total time consumption. The capacitance value corresponding to the TSV needs to be small and stable in order to increase the circuit's signal transmission speed.

### SUMMARY OF THE INVENTION

Accordingly, an interconnection structure of a semiconductor device is provided in the disclosure, wherein the TSV has a small and stable capacitance value, and the signal transmission speed of the interconnection structure of the semiconductor device is further enhanced.

The interconnection structure of the semiconductor device is constructed in a semiconductor substrate. The interconnection structure includes a first through silicon via and a second through silicon via. The first through silicon via penetrates the semiconductor substrate. The second through silicon via penetrates the semiconductor substrate. The first through silicon via and the second through silicon via are spaced from each other by a distance. Herein the distance is ranged from 2 μm to 40 μm.

According to an exemplary embodiment of the disclosure, the distance is ranged from 10 μm to 40 μm.

According to an exemplary embodiment of the disclosure, the first through silicon via is adapted to transmit a radio frequency signal, a first end of the second through silicon via is connected to a predetermined voltage, and a second end of the second through silicon via is connected to a ground voltage.

According to an exemplary embodiment of the disclosure, the first through silicon via is adapted to transmit a digital signal, a first end of the second through silicon via is connected to a predetermined voltage, and a second end of the second through silicon via is connected to a ground voltage.

According to an exemplary embodiment of the disclosure, the first through silicon via is adapted to transmit a digital signal with a frequency lower than 1 MHz, and the second through silicon via is connected to a high frequency signal with a frequency higher than 0.5 MHz.

According to an exemplary embodiment of the disclosure, the first through silicon via and the second through silicon via are two pillars parallel to each other.

According to an exemplary embodiment of the disclosure, the first through silicon via is a pillar and the second through silicon via is a tube surrounding the first through silicon via.

In light of the above, in the interconnection structure of the semiconductor device of the disclosure, two through silicon vias are disposed so that a stable capacitance structure can be equivalently formed between the two through silicon vias. As such, because of the small and stable capacitance value provided by the capacitance structure, the signal transmission speed of the interconnection structure of the semiconductor device can be effectively improved.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the invention.

FIG. 1 schematically shows a capacitance-voltage characteristic curve of a typical single TSV.

FIG. 2 is a schematic view illustrating an interconnection structure of a semiconductor device according to an exemplary embodiment of the disclosure.

FIG. 3A is a schematic view illustrating an equivalent circuit diagram of an interconnection structure of a semiconductor device according to an exemplary embodiment of the disclosure.

FIG. 3B is a schematic view illustrating the equivalent circuit diagram of the interconnection structure of the semiconductor device according to FIG. 3A.

FIG. 4 shows a C-V measurement result of the TSV illustrated in the embodiment of FIG. 2.

FIG. 5A is a schematic view illustrating when an interconnection structure of a semiconductor device is used for transmitting a radio frequency signal according to an exemplary embodiment of the disclosure.

FIG. 5B is a schematic view illustrating when an interconnection structure of a semiconductor device is used for transmitting a digital signal according to an exemplary embodiment of the disclosure.

FIG. 5C is a schematic view illustrating when an interconnection structure of a semiconductor device is used for transmitting a digital signal according to an exemplary embodiment of the disclosure.

FIG. 6A is a schematic top view illustrating an interconnection structure of a semiconductor device according to an exemplary embodiment of the disclosure.

FIG. 6B is a schematic top view illustrating an interconnection structure of a semiconductor device according to another exemplary embodiment of the disclosure.

FIG. 7 is a schematic view illustrating an interconnection structure of a semiconductor device according to an exemplary embodiment of the disclosure.

### DESCRIPTION OF EMBODIMENTS

Descriptions of the invention are given with reference to the exemplary embodiments illustrated with accompanied drawings, wherein same or similar parts are denoted with same reference numerals. In addition, whenever possible, identical or similar reference numbers stand for identical or similar elements/components in the figures and the embodiments.

People having ordinary skill in the art of the invention field might understand that a through silicon via (TSV) disposed between two chips stacked together can be used for transmitting signals between the two chips stacked together. Generally speaking, since through silicon vias have similar structure as metal oxide semiconductors (MOS), the capacitance value of the through silicon vias have the characteristics of MOS capacitance (MOS CAP).

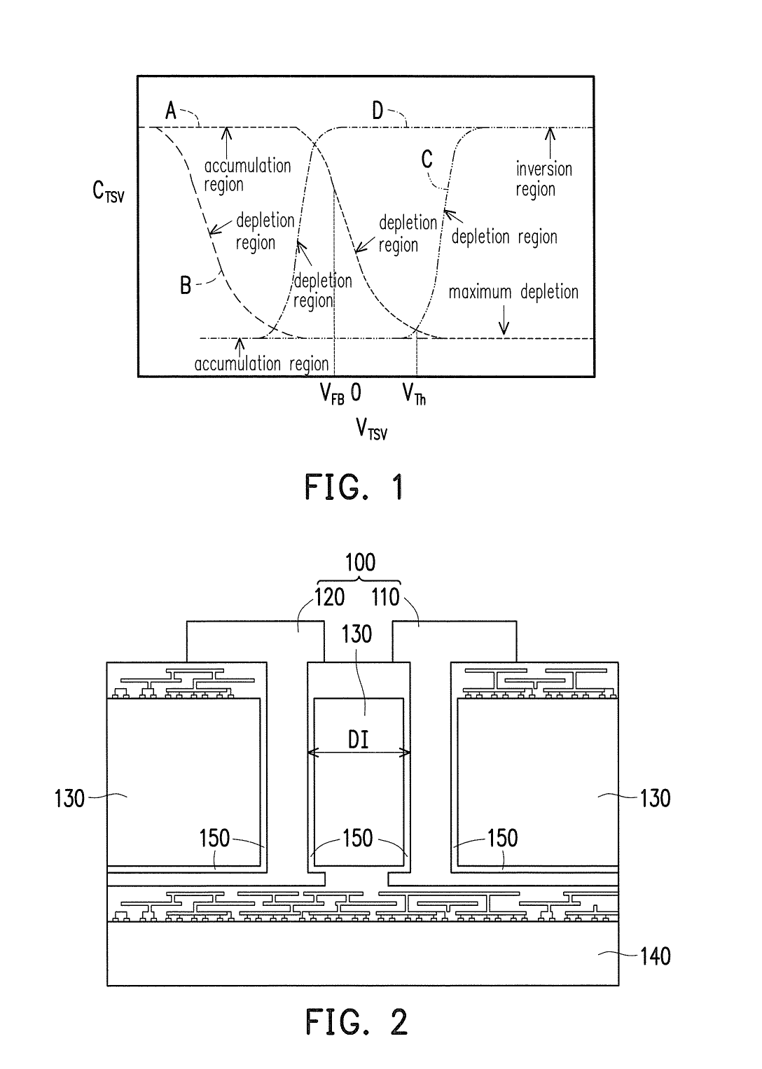

FIG. 1 schematically shows a capacitance-voltage characteristic curve of a typical single TSV. In the embodiment, the four curves shown in FIG. 1 respectively represents capacitance-voltage curves (C-V curves) of TSV when the TSV capacitance is applied signals with different frequencies. Herein the curve A represents the C-V curve of a higher flat-band voltage when a high frequency signal is applied to TSV, for example. The curve B represents the C-V curve of a higher flat-band voltage when a high frequency signal is applied to TSV, for example. The curve C represents the C-V curve of a lower flat-band voltage when a low frequency signal is applied to TSV, for example. The curve D represents the C-V curve of a lower flat-band voltage when a low frequency signal is applied to TSV, for example.

Taking the curve A as an example, with the increase of the voltage applied to TSV (V_{TSV}), the capacitance value of TSV (C_{TSV}) may sequentially pass through the accumulation region, the depletion region and the maximum depletion region. Herein the accumulation region may be defined as the region of V_{TSV}≦V_{FB}, and V_{FB} is the flat-band voltage, for example. Herein the depletion region may be defined as the region of V_{FB}≦V_{TSV}≦V_{Th}, and V_{TH} is the threshold voltage, for example. The maximum depletion region may be defined as the region of V_{Th}≦V_{TSV}. As shown in FIG. 1, in the accumulation region, the capacitance value C_{TSV} of TSV is equal to the capacitance of the oxide layer (C_{OX}), and in the maximum depletion region, C_{TSV} is the minimum value. In the depletion region, since the value of C_{TSV} is not a constant, the depletion region becomes an imperfect working region, comparatively, when TSV is applied a high frequency signal. In addition, since the value of C_{TSV} reaches its minimum value in the maximum depletion region, the maximum depletion region becomes a perfect working region, comparatively, when TSV is applied a high frequency signal. Similar to the curve A, with the increase of the value of V_{TSV}, the curve B may also sequentially pass through the accumulation region, the depletion region and the maximum depletion region. Individual characteristic of TSV in these regions can be referred to the curve A, and it is not repeated herein.

Taking the curve C as an example, with the increase of the value of V_{TSV}, C_{TSV} of TSV may also sequentially pass through the accumulation region, the depletion region and the inversion region. Herein, since the value of C_{TSV} reaches its minimum value in the accumulation region, the accumulation region becomes a perfect working region, comparatively, when TSV is applied a low frequency signal. And since the value of C_{TSV} is yet not constant in the depletion region, the depletion region may be an imperfect working region when TSV is applied a low frequency signal. Similar to the curve C, with the increase of the value of V_{TSV}, the curve D may also sequentially pass through the corresponding accumulation region, depletion region and inversion region. Individual characteristic of TSV in these regions can be referred to the curve C, and it is not repeated herein.

In the embodiment illustrated in the disclosure, by disposing a TSV and another TSV which are in an appropriate distance and can be coupled to each other, it is possible that TSVs which are mainly used for transmitting signals may have small and stable capacitance values. As such, the transmission speed of signals between the two chips stacked together can be effectively increased, and the efficiency of the entire circuit can be enhanced.

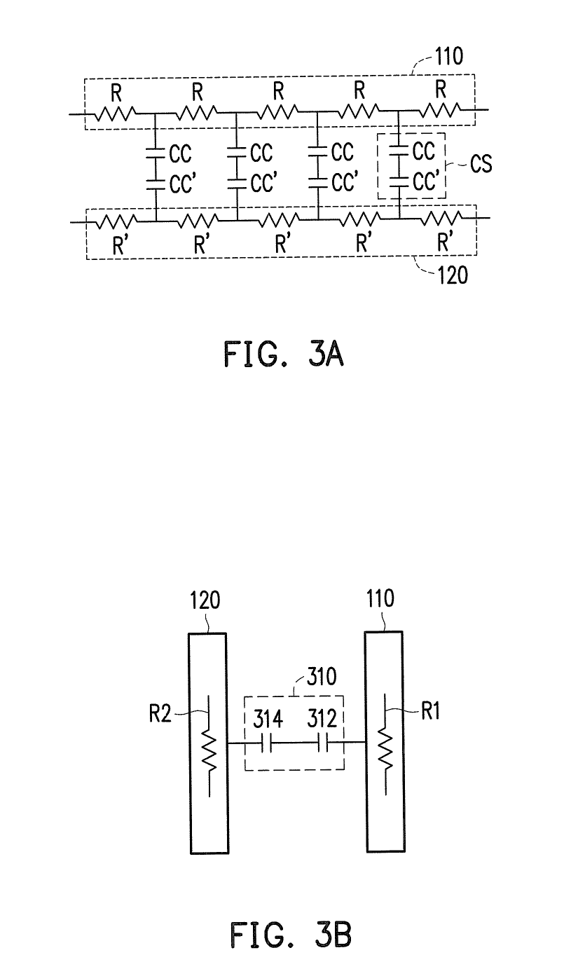

FIG. 2 is a schematic view illustrating an interconnection structure of a semiconductor device according to an exemplary embodiment of the disclosure. Please refer to FIG. 2, the interconnection structure 100 of the semiconductor device includes TSV 110 and TSV 120. As illustrated in FIG. 1, TSVs 110 and 120 penetrate the semiconductor substrate 130, and the dielectric layer 150 (e.g., silicon dioxide) is disposed on the contact surface located between TSVs 110 and 120 and the semiconductor substrate 130. In the embodiment, TSV 110 may be used for transmitting signals between chips located outside the semiconductor substrate 130 (not shown) and the chip 140. Similarly, TSV 120 may also be used for transmitting signals between chips located outside the semiconductor substrate 130 (not shown) and the chip 140. In the embodiment, TSV 110 and TSV 120 are spaced from each other by a distance DI. Herein the distance DI is ranged from 2 μm to 40 μm. Specifically, the distance DI needs to be greater than twice of the depletion width generally, so as to comply with the design rule of integrated circuit design. Additionally, in order to prevent from coupling with TSV of interconnection structure of other semiconductor device (not shown), the distance DI needs to be smaller than a particular range. Therefore, the range of the distance DI being from 2 μm to 40 μm may simultaneously satisfy the conditions of being greater than twice of the depletion width and preventing from coupling with TSV of interconnection structure of other semiconductor device. More specifically, the distance DI may be set to be ranged from 10 μm to 40 μm.

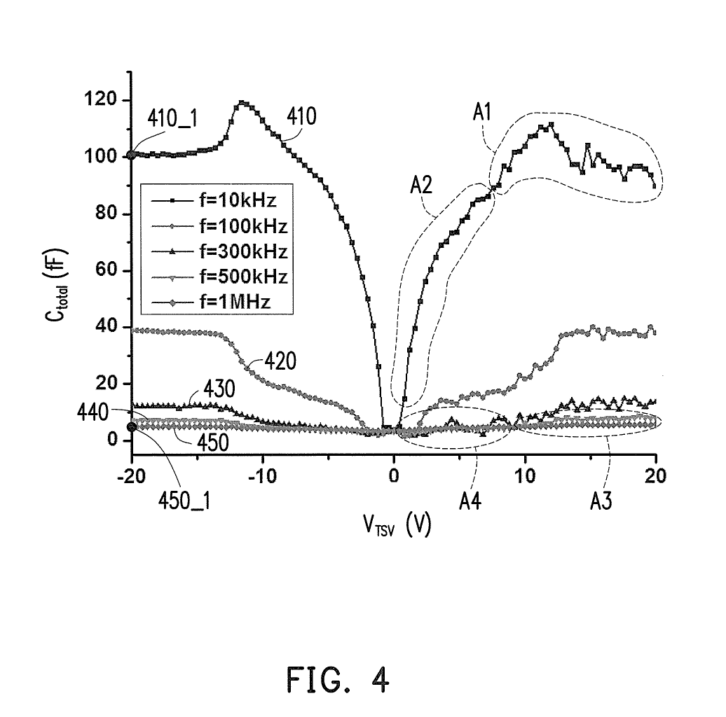

The electrical characteristic of TSV 110 and TSV 120 of the structure shown in FIG. 2 can be represented by the equivalent circuit shown in FIG. 3, for example. FIG. 3A is a schematic view illustrating an equivalent circuit diagram of an interconnection structure of a semiconductor device according to an exemplary embodiment of the disclosure. In the embodiment, both TSV 110 and TSV 120 are conductive materials thus may be represented by a plurality of equivalent resistors connected in series R and R′, respectively. In addition, the distance between TSV 110 and TSV 120 is substantially equal to the distance DI, such that a plurality of capacitance structures CS (e.g., including capacitance CC and capacitance CC′) each having a specific capacitance value may be equivalently formed between TSV 110 and TSV 120. For the convenience of illustration, the circuit diagram of FIG. 3A is simplified as shown in FIG. 3B.

FIG. 3B is a schematic view illustrating the equivalent circuit diagram of the interconnection structure of the semiconductor device according to FIG. 3A. In the embodiment, the equivalent resistors R1 and R2 respectively represent TSV 110 and TSV 120. In addition, the characteristic between TSV 110 and TSV 120 may be represented by the capacitance structure 310 (e.g., capacitance 312 and capacitance 314 connected in series). Since the capacitance structure 310 is formed by the series connection of the capacitance 312 and the capacitance 314, the capacitance value (Cₜₒₜₐₗ) of the capacitance structure 310 may be obtained according to the equation Cₜₒₜₐₗ⁻¹=C₁⁻¹+C₂⁻¹, wherein C₁ and C₂ respectively represents the capacitance values of capacitance 312 and capacitance 314.

On the other hand, since the distance between TSV 110 and TSV 120 remains a constant DI, the capacitance structure formed by the coupling of TSV 110 and TSV 120 is quite stable. Accordingly, when TSV 110 (or TSV 120) is actually applied to transmitting signals to the chip 140, a higher transmission speed can be achieved because of the corresponding stable capacitance value of the aforementioned stable capacitance structure.

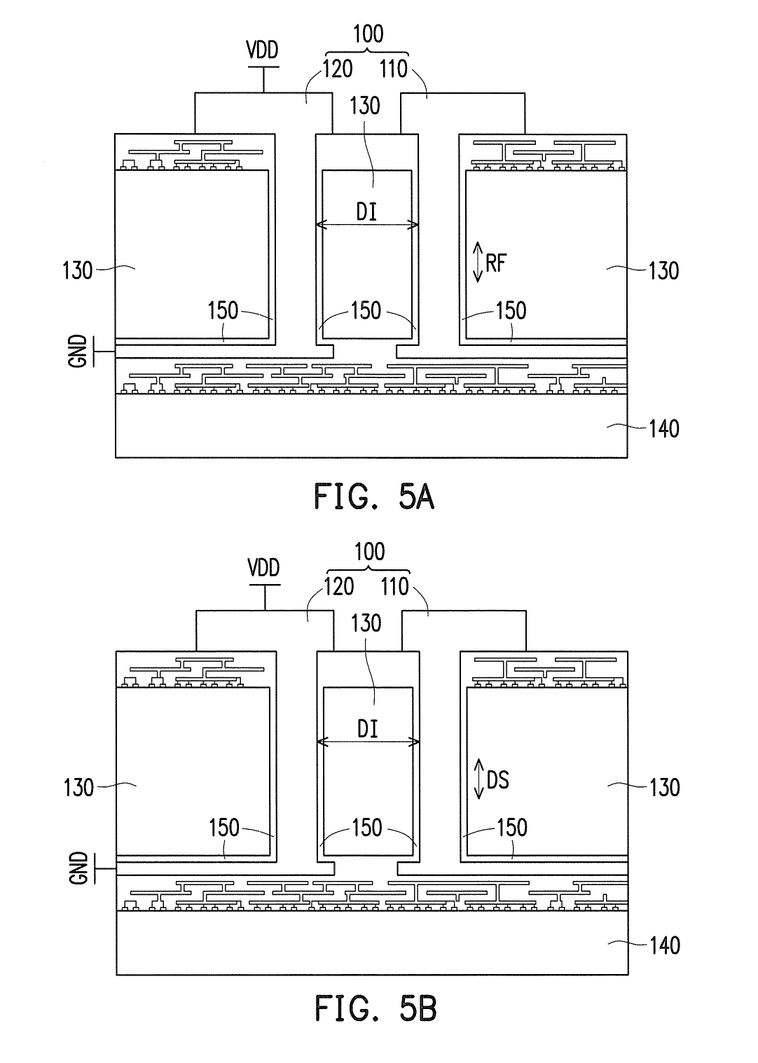

In order to verify that the structure shown in FIG. 2 and FIG. 3 can actually obtain a better C-V characteristic, people having ordinary skill in the art of the invention field may apply probing TSV method to measure the C-V characteristic of TSV 110 and TSV 120 under different frequency testing signals, and the measurement result is as shown in FIG. 4.

FIG. 4 shows a C-V measurement result of the through silicon vias according to the embodiment illustrated in FIG. 2. In the embodiment, the distance DI substantially equal to 40 μm is employed in the verification of the efficiency of the interconnection structure 100 of the semiconductor device. In FIG. 4, different curves represent the testing signals with different frequencies applied to TSV 110 and TSV 120. Herein the curves 410 to 450 are the C-V characteristic curves of TSV 110 and TSV 120 when the frequencies of testing signals are 10 kHz, 100 kHz, 300 kHz, 500 kHz and 1 MHz, respectively.

As shown in FIG. 4, when the testing signals with different frequencies are applied to TSV 110 and TSV 120, the C-V characteristic curves of TSV 110 and TSV 120 are substantially symmetric (with respect to V_{TSV} is equal to 0). Additionally, with the increase of the frequencies of the testing signals, the capacitance values Cₜₒₜₐₗ of TSV 110 and TSV 120 corresponding to different V_{TSV} may become smaller. Moreover, when the frequency of the testing signal is increased to 1 MHz, the corresponding C-V characteristic curve may appear to have low, average and stable capacitance values. The principle which forms each of the curves shown in FIG. 4 is described in the following referring to FIG. 1 and FIG. 3B.

For instance, when a testing signal with low frequency and high V_{TSV} is applied to TSV 110, TSV 110 may operate in the inversion region of the curve D of FIG. 1. At this moment, TSV 120 may located in the accumulation region of the curve D since having a voltage polarity opposite to TSV 110. Therefore, the capacitance value (Cₜₒₜₐₗ) of the capacitance structure 310 may be obtained according to the equation Cₜₒₜₐₗ⁻¹=C₁⁻¹+C₂⁻¹=C_{acc}⁻¹+Cᵢₙᵥ⁻¹. Herein C_{acc} is the capacitance value of TSV 110 in the accumulation region, and Cᵢₙᵥ, is the capacitance value of TSV 120 in the inversion region. Thus, the capacitance value (Cₜₒₜₐₗ) of the capacitance structure 310 may appear to be comparatively higher. Taking the curve 410 (i.e., corresponding to the C-V characteristic curve of low frequency testing signal) as an example, the region corresponding to high V_{TSV} is the region A1 of FIG. 4, for example. However, the disclosure is not limited thereto.

For another instance, when a testing signal with low frequency and low V_{TSV} is applied to TSV 110, TSV 110 may operate in the depletion region of the curve D of FIG. 1. At this moment, TSV 120 may also located in the depletion region of the curve D since having a voltage polarity opposite to TSV 110. Therefore, the capacitance value (Cₜₒₜₐₗ) of the capacitance structure 310 may be obtained according to the equation Cₜₒₜₐₗ⁻¹=C₁⁻¹+C₂⁻¹=C_{d1}⁻¹+C_{d2}⁻¹. Herein C_{dl} is the capacitance value of TSV 110 in the depletion region, and C_{d2} is the capacitance value of TSV 120 in the depletion region. Thus, the capacitance value (Cₜₒₜₐₗ) of f the capacitance structure 310 may appear to be comparatively lower. Again taking the curve 410 (i.e., corresponding to the C-V characteristic curve of low frequency testing signal) as an example, the region corresponding to low V_{TSV} is the region A2 of FIG. 4, for example. However, the disclosure is not limited thereto.

Moreover, when a testing signal with high frequency and high V_{TSV} is applied to TSV 110, TSV 110 may operate in the maximum depletion region of the curve A of FIG. 1. At this moment, TSV 120 may located in the accumulation region of the curve A since having a voltage polarity opposite to TSV 110. Therefore, the capacitance value (Cₜₒₜₐₗ), of the capacitance structure 310 may be obtained according to the equation Cₜₒₜₐₗ⁻¹=C₁⁻¹+C₂⁻¹+C_{acc}⁻¹+C_{dd}⁻¹. Herein C_{dd} is the capacitance value of TSV 110 in the maximum depletion region, and C_{acc} is the capacitance value of TSV 120 in the accumulation region. Thus, the capacitance value (Cₜₒₜₐₗ) of the capacitance structure 310 may appear to be comparatively lower. Taking the curve 450 (i.e., corresponding to the C-V characteristic curve of high frequency testing signal) as an example, the region corresponding to high V_{TSV} is the region A3 of FIG. 4, for example. However, the disclosure is not limited thereto.

Moreover, when a testing signal with high frequency and low V_{TSV} is applied to TSV 110, TSV 110 may operate in the depletion region of the curve A of FIG. 1. At this moment, TSV 120 may also located in the depletion region of the curve A since having a voltage polarity opposite to TSV 110. Therefore, the capacitance value (Cₜₒₜₐₗ) of the capacitance structure 310 may be obtained according to the equation Cₜₒₜₐₗ⁻¹=C₁⁻¹+C₂⁻¹=C_{d1}⁻¹+C_{d2}⁻¹. Herein C_{dl} is the capacitance value of TSV 110 in the depletion region, and C_{d2} is the capacitance value of TSV 120 in the depletion region. Thus, the capacitance value (Cₜₒₜₐₗ) of the capacitance structure 310 may appear to be comparatively lower. Taking the curve 450 (i.e., corresponding to the C-V characteristic curve of high frequency testing signal) as an example, the region corresponding to low V_{TSV} is the region A4 of FIG. 4, for example. However, the disclosure is not limited thereto.

As aforementioned, if the capacitance values of TSV 110 and TSV 120 have a small and stable characteristic, the transmission speed of the interconnection structure 100 of the semiconductor device may be higher in the signal transmitting application. Taking the reference point 410_1 of FIG. 4 as an example, it is the capacitance value of the curve 410 corresponding to −20V of V_{TSV}. And then, taking the reference point 450_1 of FIG. 4 as an example, it is the capacitance value of the curve 450 corresponding to −20V of V_{TSV}. As shown in FIG. 4, the capacitance value corresponding to the reference point 410_1 is about 100 fF, and the capacitance value corresponding to the reference point 450_1 is about 5 fF. In other words, if the frequency of the testing signal is increased from 10 kHz to 1 MHz, the capacitance value corresponding to −20V of V_{TSV} may decrease about 20 times, thus the signal transmission speed of the interconnection structure 100 as applied in a semiconductor device can be significantly improved.

In addition, since the structures of TSV 110 and TSV 120 are substantially similar to each other, in the fabricating process of the interconnection structure 100 of the semiconductor device in the embodiment of the disclosure, no any other extra fabricating cost is needed for developing a new structure but only the general fabricating process of TSV is used for fabricating TSV 110 and TSV 120. Namely, the fabricating complexity of the interconnection structure of the semiconductor device is increased.

In one exemplary embodiment, if the interconnection structure 100 of the semiconductor device is used for signal transmission, only one of the TSV 100 and TSV 120 is used for signal transmission, and the other TSV which is not used for signal transmission can be connected to a different voltage according to applying condition of the interconnection structure 100 of the semiconductor device.

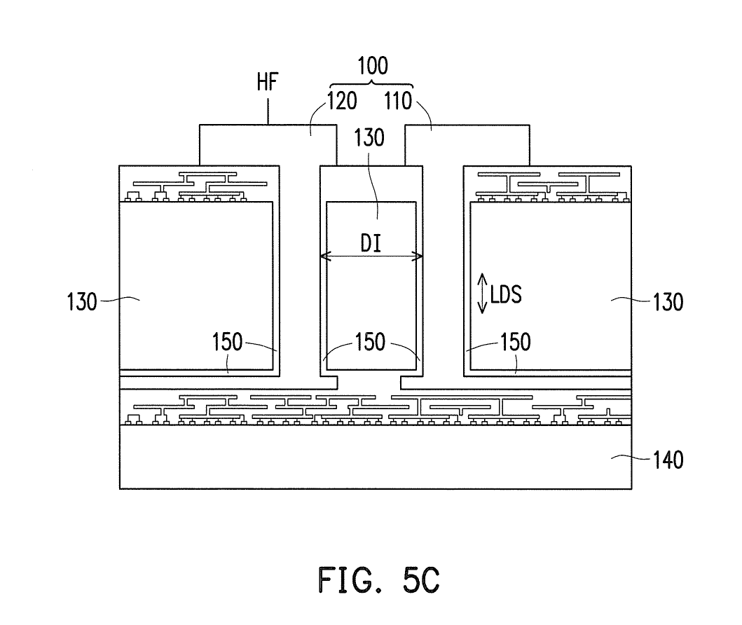

FIG. 5A is a schematic view illustrating when an interconnection structure of a semiconductor device is used for transmitting a radio frequency signal according to an exemplary embodiment of the disclosure. In the embodiment, in the condition of TSV 110 being used for transmitting a radio frequency signal RF, the first end of TSV 120 is connected to a predetermined voltage VDD, and the second end of TSV 120 is connected to a ground voltage GND. Or in other embodiments, the second end of TSV 120 can be connected to a floating voltage.

FIG. 5B is a schematic view illustrating when an interconnection structure of a semiconductor device is used for transmitting a digital signal according to an exemplary embodiment of the disclosure. In the embodiment, in the condition of TSV 110 being used for transmitting a digital signal DS, the first end of TSV 120 is connected to a predetermined voltage VDD, and the second end of TSV 120 is connected to a ground voltage GND. Or in other embodiments, the second end of TSV 120 can also be connected to a floating voltage.

FIG. 5C is a schematic view illustrating when an interconnection structure of a semiconductor device is used for transmitting a digital signal according to an exemplary embodiment of the disclosure. In the embodiment, in the condition of TSV 110 being used for transmitting a digital signal LDS (e.g., a digital signal with a frequency lower than 1 MHz), the first end of TSV 120 is connected to a high frequency signal HF of 0.5 MHz, and the second end of TSV 120 is connected to a ground voltage GND. As such, when TSV 110 transmits a digital signal LDS, TSV 120 with the high frequency signal HF reacts and provides coupling effect to TSV 110.

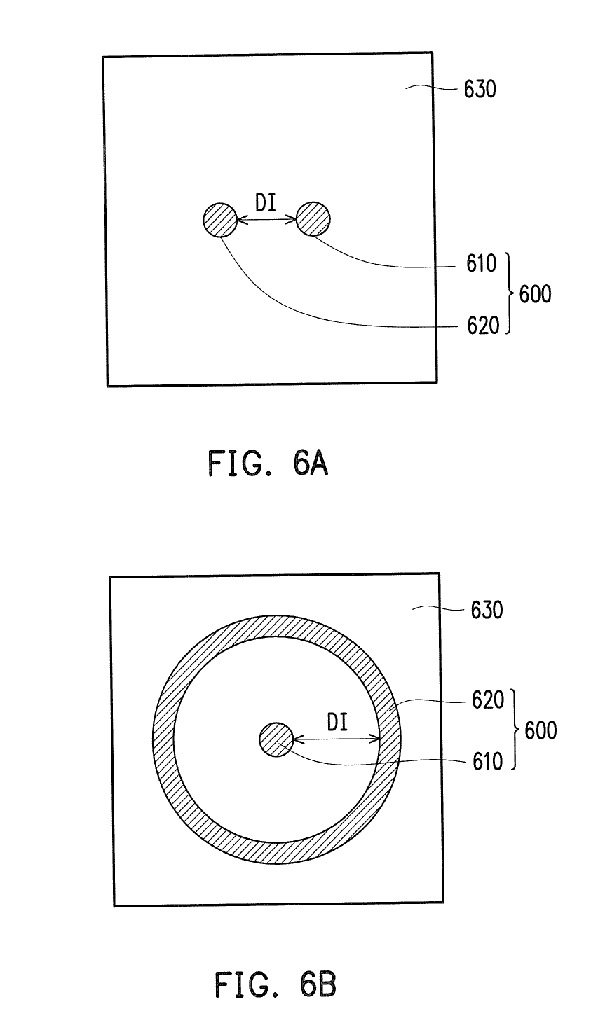

FIG. 6A is a schematic top view illustrating an interconnection structure of a semiconductor device according to an exemplary embodiment of the disclosure. In the embodiment, the interconnection structure 600 of the semiconductor device includes TSV 610 and TSV 620. Herein TSV 610 and TSV 620 penetrate the semiconductor substrate 630 and are two pillars parallel and spaced from each other by a distance DI (between 2 μm and 40 μm). FIG. 6B is a schematic top view illustrating an interconnection structure of a semiconductor device according to another exemplary embodiment of the disclosure. In the embodiment, TSV 610 may be a pillar penetrating the semiconductor substrate 630, and TSV 620 may be a tube penetrating the semiconductor substrate 630 and surrounding the TSV 110. In addition, TSV 620 may be disposed in the interconnection structure 600 of the semiconductor device in a manner of being spaced from the other TSV 610 by a distance DI (between 2 μm and 40 μm).

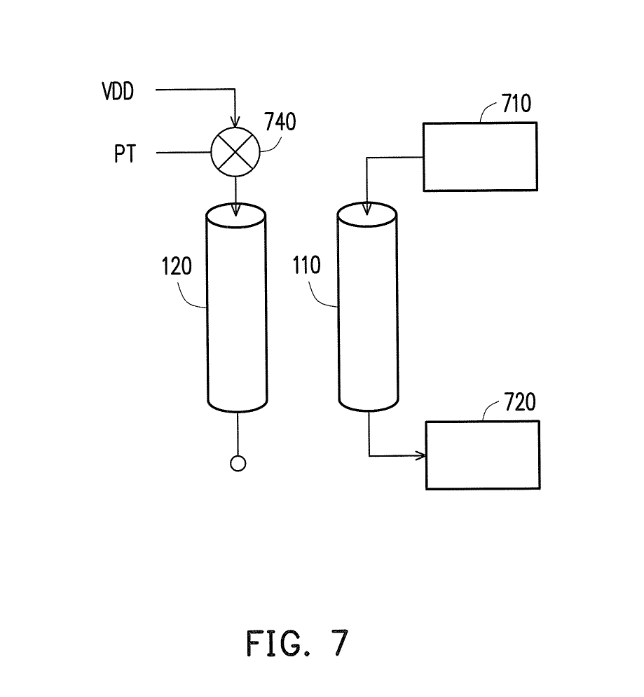

FIG. 7 is a schematic view illustrating an interconnection structure of a semiconductor device according to an exemplary embodiment of the disclosure. In the embodiment, TSV 110 may be connected between the first chip 710 and the second chip 720 (e.g., the chip 140) and used for transmitting digital signals LDS, DS and/or radio frequency RF signals as mentioned above between the first chip 710 and the second chip 720. TSV 720 may be coupled to the multiplier 740. The multiplier 140 may be used for multiplying the predetermined voltage VDD and the pulse PT and then transmits to TSV 120. In the structure illustrated in FIG. 7, when TSV 110 transmits signals between the first chip 710 and the second chip 720, TSV 120 may provide coupling effect to TSV 110 as mentioned above. As such, a stable capacitance structure may be equivalently formed between TSV 110 and TSV 120, further the signal transmission speed between the first chip 710 and the second chip 120 may be increased.

In light of the foregoing, in the interconnection structure of the semiconductor device of the disclosure, beside the TSV for signal transmission, another TSV having a similar structure is also disposed, so that a stable capacitance structure can be equivalently formed between the two TSVs. As such, because of the small and stable capacitance value provided by the capacitance structure, the interconnection structure of the semiconductor device can effectively increase the signal transmission speed. Furthermore, since the two TSVs included in the interconnection structure of the semiconductor are substantially structurally similar to each other, the disposing of the extra TSV would not increase the fabricating complexity of the interconnection structure of the semiconductor device.

Although the present invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

1. An interconnection structure of a semiconductor device, the interconnection structure constructed in a semiconductor substrate, the interconnection structure comprising:
a first through silicon via penetrating the semiconductor substrate; and
a second through silicon via penetrating the semiconductor substrate, the first through silicon via and the second through silicon via spaced from each other by a distance,
wherein the distance is ranged from 2 μm to 40 μm.

2. The interconnection structure of the semiconductor device as claimed in claim 1, wherein the distance is ranged from 10 μm to 40 μm.

3. The interconnection structure of the semiconductor device as claimed in claim 1, wherein the first through silicon via is adapted to transmit a radio frequency signal, a first end of the second through silicon via is connected to a predetermined voltage, and a second end of the second through silicon via is connected to a ground voltage.

4. The interconnection structure of the semiconductor device as claimed in claim 1, wherein the first through silicon via is adapted to transmit a digital signal, a first end of the second through silicon via is connected to a predetermined voltage, and a second end of the second through silicon via is connected to a ground voltage or a floating voltage.

5. The interconnection structure of the semiconductor device as claimed in claim 1, wherein the first through silicon via is adapted to transmit a digital signal with a frequency lower than 1 MHz, and the second through silicon via is connected to a high frequency signal with a frequency higher than 0.5 MHz.

6. The interconnection structure of the semiconductor device as claimed in claim 1, wherein the first through silicon via and the second through silicon via are two pillars parallel to each other.

7. The interconnection structure of the semiconductor device as claimed in claim 1, wherein the first through silicon via is a pillar and the second through silicon via is a tube surrounding the first through silicon via.
